(19) United States
(12) Patent Application Publication
(10) Pub. No.: US 2018/0144892 A1
(43) Pub. Date: May 24, 2018

(54) MAGNETIC SHIELD STRUCTURE

(71) Applicant: OMRON Corporation, Kyoto (JP)

(72) Inventors: Seiki Shimoda, Kumamoto (JP); Masaaki Abe, Kumamoto (JP)

(73) Assignee: OMRON Corporation, Kyoto (JP)

(21) Appl. No.: 15/876,069

(22) Filed: Jan. 19, 2018

Related U.S. Application Data
(63) Continuation of application No. PCT/JP2016/075114, filed on Aug. 29, 2016.

(30) Foreign Application Priority Data
Sep. 11, 2015 (JP) 2015-179234

(51) Int. Cl. H01H 45/10; H01H 45/02; H05K 9/00

(52) U.S. Cl. CPC H01H 45/10; H05K 9/0007; H01H 45/02

(57) ABSTRACT

A magnetic shield structure includes a housing made of a dielectric material, and a magnetic shield body formed by metal plating. The magnetic shield body is partially provided on at least one of an outer surface and an inner surface that form a surface of the housing made of the dielectric material.

### BACKGROUND

### Technical Field

The present invention relates to a magnetic shield structure, and particularly a magnetic shield structure formed by performing metal plating on a housing.

### Related Art

As an example of a magnetic shield structure, there has been a high-frequency relay that is magnetically shielded by fitting a separate metal case to a relay body and covering the entire relay body (Patent Document 1).

Patent Document 1: Japanese Unexamined Patent Publication No. 2000-340084

### SUMMARY

However, the high-frequency relay is made up by covering, with the metal case, the relay body formed by covering a body with a cover. Hence the high-frequency relay requires the separate metal case, the number of parts and the number of assembling steps are large, and the productivity is low.

Further, external dimensions of the metal case and the positional relationship between the metal case and a high-frequency transmission component affect high-frequency characteristics. For this reason, high dimensional accuracy and assembly accuracy are required in manufacturing and assembling the metal case, and the manufacturing and the assembly are thus not easy.

The metal case covers the entire exposed surface, except for the installation surface, of the relay body. This leads to a problem in which desired high-frequency characteristics cannot be obtained due to the metal case covering an unnecessary region and a region that causes deterioration in characteristics of a transmission path structure.

In view of the above problems, an object of the present invention is to provide a magnetic shield structure having high productivity and excellent high-frequency characteristics, and easy to manufacture and assembly.

For solving the above problem, a magnetic shield structure according to the present invention is partially provided with a magnetic shield body, formed by metal plating, on at least one of an outer surface and an inner surface that form the surface of a housing made of a dielectric material.

According to the present invention, since the magnetic shield body is provided directly on the housing, it is possible to obtain a magnetic shield structure having high productivity with smaller numbers of parts and assembling steps.

Also, a magnetic shield body is formed directly in a region that requires the housing. Hence it is possible to prevent deterioration in high-frequency characteristics based on the variations of the dimensional accuracy and the assembly accuracy in the housing.

Then, a magnetic shield body is formed only in a region that requires the housing. Therefore, as in the conventional example, the magnetic shield body is not formed in an unnecessary region or a region that causes deterioration in characteristics of a transmission path structure. As a result, the effect of obtaining a magnetic shield structure with excellent high-frequency characteristics is provided.

### BRIEF DESCRIPTION OF THE DRAWINGS

FIG. 1 is a perspective view illustrating an electromagnetic relay of a first embodiment, to which a magnetic shield structure according to the present invention has been applied.

FIG. 2 is a perspective view illustrating a state where a case has been removed from the electromagnetic relay illustrated in FIG. 1.

FIG. 3 is a front sectional view of the electromagnetic relay illustrated in FIG. 1.

FIG. 4 is a central front sectional view of the electromagnetic relay illustrated in FIG. 1.

FIG. 5 is a side sectional view of the electromagnetic relay illustrated in FIG. 1.

FIG. 6 is a partially enlarged sectional view of the electromagnetic relay illustrated in FIG. 1.

FIG. 7 is a perspective view of only a magnetic shield body illustrated in FIG. 1.

FIG. 8 is a graph illustrating analysis results of Example and Comparative Example according to the first embodiment.

FIG. 9 is a perspective view of a case illustrating a second embodiment of a magnetic shield structure according to the present invention.

FIG. 10 is a perspective view of only a magnetic shield body provided in the case illustrated in FIG. 9.

FIG. 11 is a perspective view of only the magnetic shield body located on an inner side in FIG. 10.

FIG. 12 is a perspective view of the case illustrated in FIG. 9 viewed from different viewpoints.

FIG. 13 is a perspective view of only the magnetic shield body illustrated in FIG. 10 viewed from different angles.

FIG. 14 is a partially enlarged sectional view of the case illustrated in FIG. 9.

FIG. 15 is a partially enlarged sectional view of only the magnetic shield body of the case illustrated in FIG. 14.

FIG. 16 is a perspective view illustrating a switch according to a third embodiment, to which a magnetic shield structure according to the present invention has been applied.

FIG. 17 is a perspective view of the switch illustrated in FIG. 16, viewed from a different viewpoint.

FIG. 18 is a central front sectional view of the switch illustrated in FIG. 16.

FIG. 19 is a perspective view illustrating a state where a case has been removed from the switch illustrated in FIG. 16.

FIG. 20 is a perspective view illustrating a state where an operation lever is removed from FIG. 19.

FIG. 21 is a perspective view illustrating a state where a base is removed from FIG. 20.

FIG. 22 is a sectional perspective view of only a magnetic shield body illustrated in FIG. 16.

FIG. 23 is an exploded perspective view illustrating a connector according to a fourth embodiment, to which a magnetic shield structure according to the present invention has been applied.

FIG. 24 is a sectional exploded perspective view of the connector illustrated in FIG. 23.

FIG. 25 is a perspective view illustrating a state where a resin molded portion is removed from the connector illustrated in FIG. 24.

FIG. 26 is a perspective view of only a magnetic shield body illustrated in FIG.

25 viewed from a different angle.

### DETAILED DESCRIPTION

A magnetic shield structure according to an aspect of the present invention is partially provided with a magnetic shield body, formed by metal plating, on at least one of an outer surface and an inner surface that form a surface of a housing made of a dielectric material.

According to this aspect, since the magnetic shield body is provided directly on the housing, it is possible to obtain a magnetic shield structure having high productivity with smaller numbers of parts and assembling steps.

Also, a magnetic shield body is formed directly in a region that requires the housing. Hence it is possible to prevent deterioration in high-frequency characteristics based on the variations of the dimensional accuracy and the assembly accuracy in the housing.

Then, a magnetic shield body is formed only in a region that requires the housing. Therefore, as in the conventional example, the magnetic shield body is not formed in an unnecessary region or a region that causes deterioration in characteristics of a transmission path structure. As a result, the effect of obtaining a magnetic shield structure with excellent high-frequency characteristics is provided.

In the magnetic shield structure according to the aspect of the present invention, the magnetic shield body may be formed by the metal plating in a region facing high-frequency transmission path disposed in the housing on the inner surface and/or the outer surface of the housing, such that a characteristic impedance of the high-frequency transmission path becomes uniform.

According to this aspect, it is unnecessary to always provide the magnetic shield body by metal plating on the entire inner surface and/or outer surface of the housing. Hence it is possible to save a raw material and obtain a magnetic shield structure with high productivity.

In a magnetic shield structure according to another aspect of the present invention, the magnetic shield body may be formed by the metal plating and a dielectric in a region facing the high-frequency transmission path disposed in the housing on the inner surface and/or the outer surface of the housing, such that a characteristic impedance of the high-frequency transmission path becomes uniform.

According to this aspect, it is unnecessary to always provide the magnetic shield body by metal plating and a dielectric on the entire inner surface and/or outer surface of the housing. Hence it is possible to save a raw material and obtain a magnetic shield structure with high productivity.

In a magnetic shield structure according to another aspect of the present invention, the housing may be made up of a base and a case fitted to the base.

According to this aspect, a highly versatile magnetic shield structure can be obtained.

In a magnetic shield structure according to a new aspect of the present invention, the magnetic shield body may be formed on at least a part of an outer surface of the case Further, the magnetic shield body may be formed on at least a part of the inner surface of the case.

According to this aspect, since the magnetic shield body can be formed in a necessary region as necessary, it is possible to obtain a magnetic shield structure having more excellent high-frequency characteristics.

In a magnetic shield structure according to another aspect of the present invention, the magnetic shield body formed on the outer surface of the case and the magnetic shield body formed on the inner surface of the case may be electrically connected by the metal plating.

According to this aspect, it is possible to obtain a magnetic shield structure having more excellent high-frequency characteristics.

In a magnetic shield structure according to another aspect of the present invention, the magnetic shield body may be provided on at least a part of a bottom surface of the base.

According to this aspect, since the magnetic shield body can be formed in a necessary region as necessary, a magnetic shield structure having a wide application can be obtained.

In a magnetic shield structure according to a new aspect of the present invention, the magnetic shield body formed on the outer surface of the case and the magnetic shield body formed on the bottom surface of the base may be electrically connected by the metal plating.

According to this aspect, it is possible to connect to the ground via the magnetic shield body provided on the bottom surface of the base.

In a magnetic shield structure according to another aspect of the present invention, the housing may be made up of a plug body and a socket body connected to the plug body.

According to this aspect, a highly versatile magnetic shield structure can be obtained.

In a magnetic shield structure according to another aspect of the present invention, the magnetic shield body may be formed by the metal plating on at least a part of the plug body. In addition, the magnetic shield body may be formed by the metal plating on at least a part of the socket body.

According to this aspect, there is an effect that a magnetic shield structure can be formed in a necessary region as necessary.

An electric/electronic component according to an aspect of the present invention includes the above magnetic shield structure.

According to this aspect, the magnetic shield structure is not limited to electromagnetic relays, switches, and connectors, and can be applied to other electric devices and electronic components having a high-frequency transmission component in a housing made of resin.

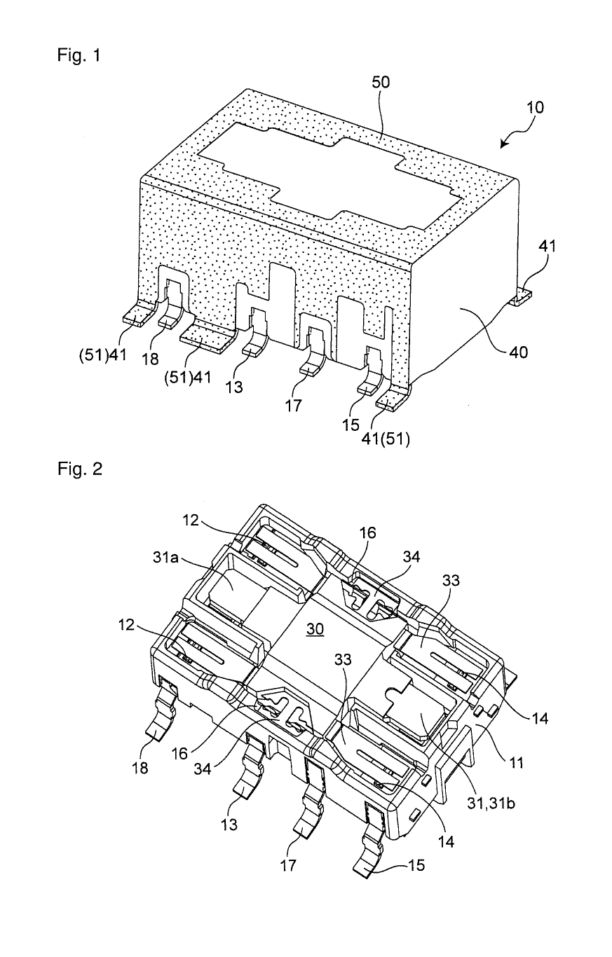

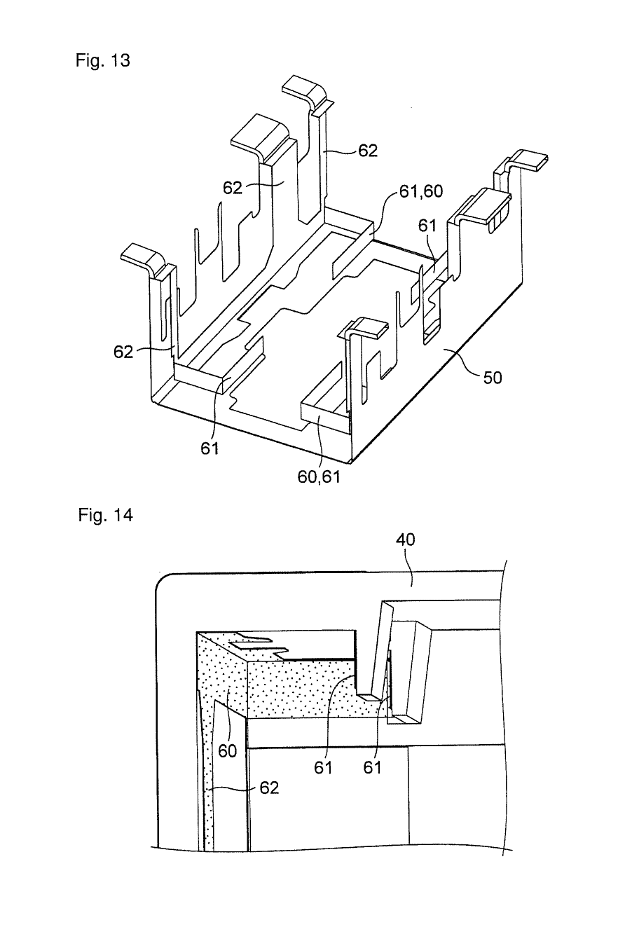

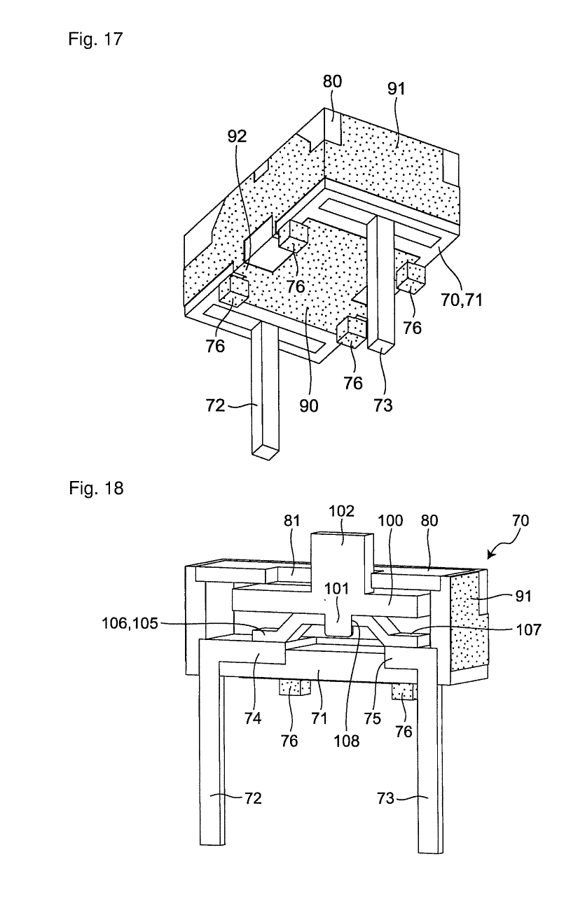

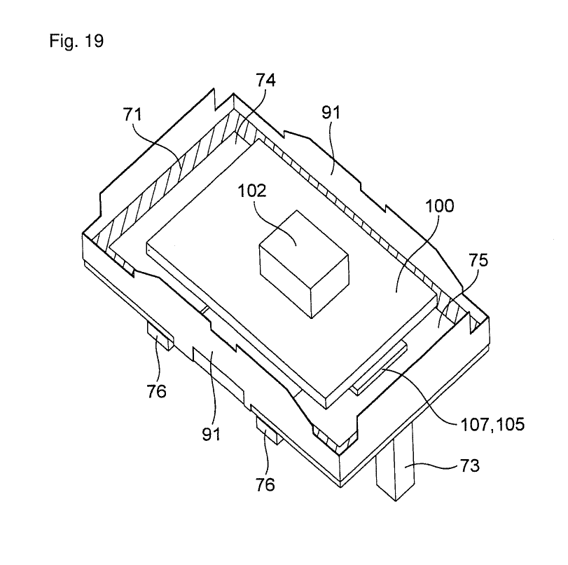

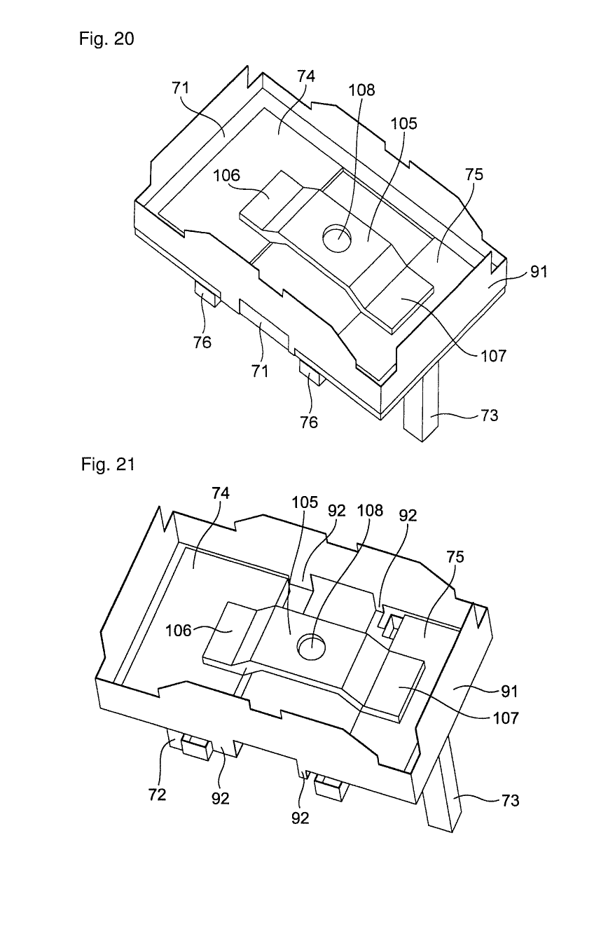

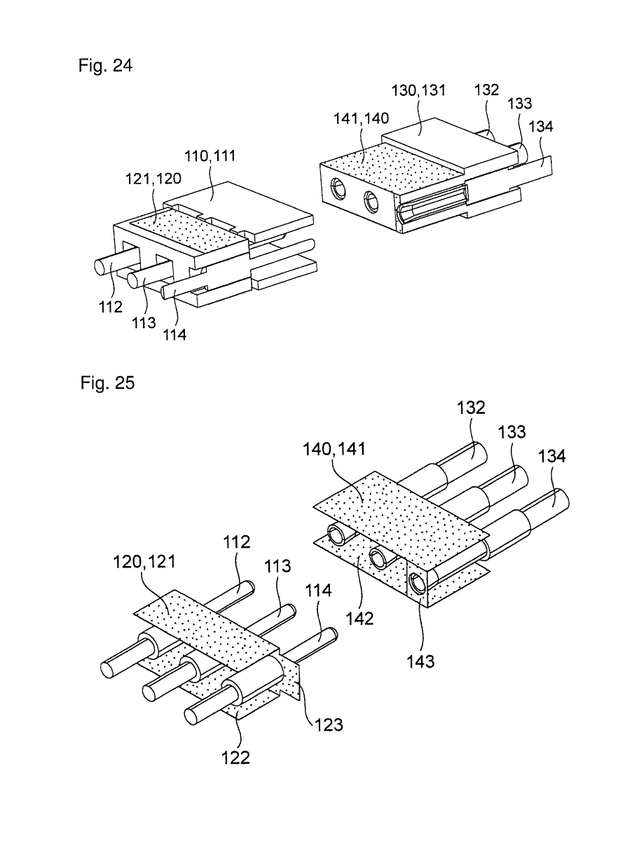

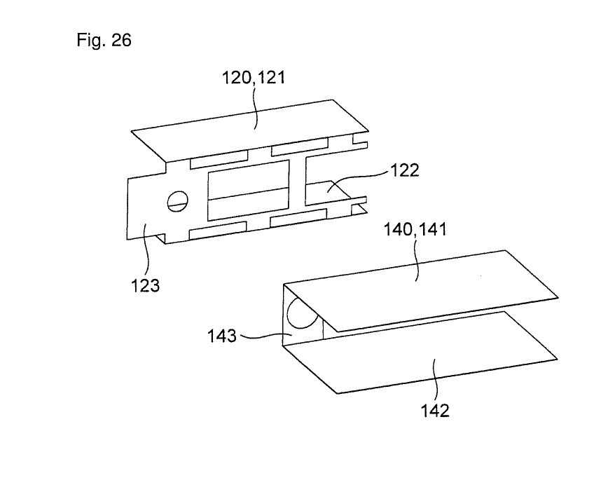

Embodiments of a magnetic shield structure according to the present invention will be described with reference to FIGS. 1 to 25.

### First Embodiment

In a first embodiment, as illustrated in FIGS. 1 to 7, a magnetic shield structure according to the present invention has been applied to a magnetically shielded self-holding type electromagnetic relay 10.

As illustrated in FIGS. 1 and 2, the electromagnetic relay 10 rotatably supports a movable block 30 in an internal space formed by fitting a case 40 to a base 11.

For convenience of description, a magnetic shield body 50 provided in the case 40 is illustrated in a dotted pattern.

As illustrated in FIGS. 2 to 6, the base 11 is formed by integrally molding an electromagnet block 20. Further, as illustrated in FIG. 2, fixed contacts 12, 14 are disposed at corner portions of the upper surface of the base 11. The fixed contacts 12, 14 are connected to fixed contact terminals 13, 15 integrally molded with the base 11, respectively. Further, the base 11 is provided with common connection receivers 16 on opposite side edges of the upper surface of the base 11. The common connection receiver 16 is connected to a common terminal 17 integrally molded with the base 11. Note that a coil terminal 18 integrally molded with the base 11 is connected to a coil 22 of the electromagnet block 20 described later.

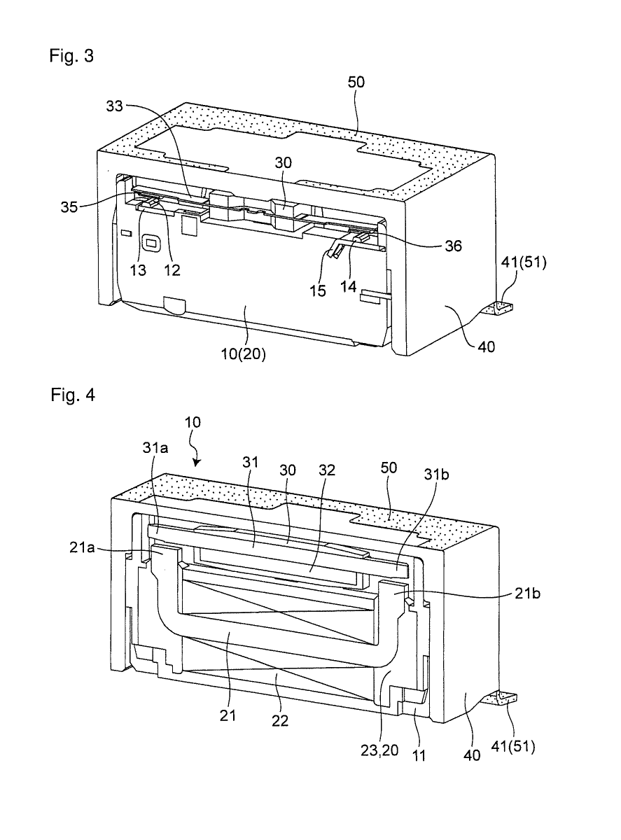

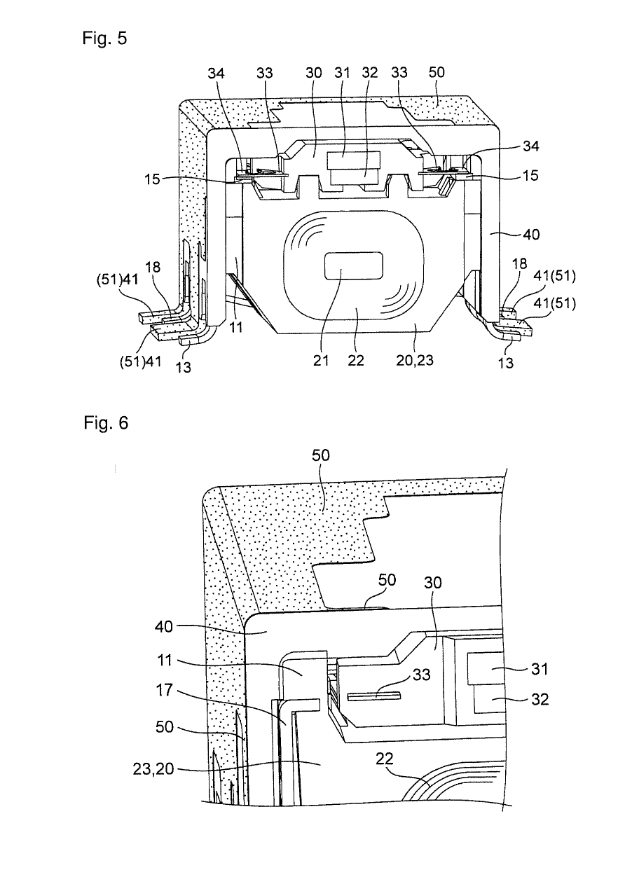

As illustrated in FIGS. 3 and 5, the electromagnet block 20 is formed by winding a coil 22 about an iron core 21 having a gate shape in cross section via an insulating sheet (not shown), to integrally mold the iron core 21 and the coil 22 with a spool 23. Magnetic pole portions 21a, 21b of the iron core 21 are exposed from both side edges of the upper surface of the base 11 (FIG. 4).

As illustrated in FIG. 4, the movable block 30 is formed by disposing a permanent magnet 32 having a plate shape on the lower surface of a movable iron piece 31 having a strip shape and disposing movable touch pieces 33, 33 in parallel on both sides of the movable iron piece 31 as illustrated in FIG. 2, to integrally mold the permanent magnet 32 and the movable touch pieces 33, 33. As illustrated in FIGS. 2 and 5, the movable touch piece 33 extends laterally from the side edge thereof, and has a connecting tongue piece 34 having a substantially planar T-shape. As illustrated in FIG. 2, the connecting tongue pieces 34 protrude on the same axial center from both side end surfaces of the movable block 30. Further, as illustrated in FIG. 3, both ends of the movable touch piece 33 have a twin contact structure in which movable contacts 35, 36 are provided on the respective divided pieces divided into two areas in the width direction.

Then, as illustrated in FIG. 5, by welding and integrating the connecting tongue piece 34 of the movable block 30 to the common connection receiver 16 of the base 11, the movable block 30 is rotatably supported. As a result, both ends 31a, 31b of the movable iron piece 31 face the magnetic pole portions 21a, 21b of the iron core 21 so as to be contactable with and separable from each other alternately. Further, the movable contacts 35, 36 of the movable touch piece 33 face the fixed contacts 12, 14 alternately so as to be contactable and separable.

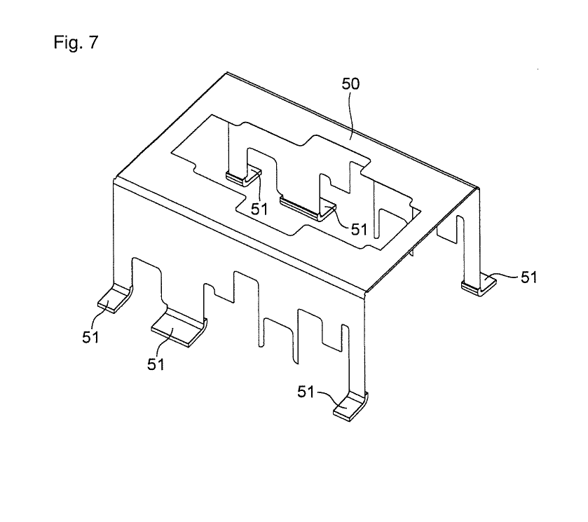

The case 40 is a resin molded product having a box shape that can be fitted to the base 11. The magnetic shield body 50 is formed on the outer peripheral surface of the case 40 by a molded interconnect devices (MID) molding method. In the MID molding method, laser irradiation is performed on a molded article formed from a material in which a resin and a conductive material are mixed, based on a predetermined pattern, and the resin is removed. Then, metal plating is performed on the exposed conductive material so as to form a desired circuit pattern. A tubular magnetic shield portion 51 is also provided on the entire surface of a terminal portion 41 extending from the opening edge of the case 40 (FIG. 7). This is for connecting to a ground of a printed circuit board (not shown) or the like.

The magnetic shield body 50 is provided based on the knowledge that high-frequency signals tend to leak if the characteristic impedance varies in the high-frequency transmission path. Therefore, in order to reduce the leakage of the high-frequency signal, the magnetic shield body 50 is formed so as to reduce variations in the characteristic impedance in the high-frequency transmission path.

In short, instead of forming the magnetic shield body by metal plating over the entire outer peripheral surface of the case 40, a suitable magnetic shield body 50 is formed in a necessary region. As a result, the magnetic shield body 50 constitutes, for example, a microstrip structure, a strip line structure, and a coplanar line structure.

The region where the magnetic shield body 50 is formed may be a region facing the high-frequency transmission path installed in the housing among the inner surface and/or the outer surface of a housing formed of a base and a case.

More specifically, it is preferable to arrange and form metal plating and/or dielectric so that the characteristic impedance of the high-frequency transmission path becomes uniform. It is a matter of course that air is also considered as a dielectric.

For example, it is preferable to arrange and form the metal plating and/or the dielectric so that the characteristic impedance in each region of the high-frequency transmission path is equal to the reference value of 50 Ω. This is because if there is a difference in characteristic impedance for each region of the high-frequency transmission path, high frequency leaks easily from the boundary of the region where the difference is present, and the high-frequency characteristics are degraded.

As the microstrip structure in this embodiment, for example, as illustrated in FIG. 6, a common terminal 17 which is a high-frequency transmission path is sandwiched between a spool 23 made of resin of an electromagnet block 20 which is a dielectric and a case 40 made of resin which is a dielectric material provided with a magnetic shield body 50.

Further, as a strip line structure, for example, as illustrated in FIG. 6, a structure in which a case 40 made of resin which is a dielectric provided with a magnetic shield body 50 is disposed above a movable touch piece 33 which is a high-frequency transmission path can be mentioned.

As a coplanar line structure, for example, as illustrated in FIG. 1, between a coil terminal 18 which is a high-frequency transmission path and a magnetic shield body 50 formed on the outer peripheral surface of a case 40 made of resin which is a dielectric, a structure in which a minute gap portion is formed can be mentioned. Similarly, the fixed contact terminals 13, 15 and the common terminal 17 constitute a coplanar line structure.

Next, a method of operating a self-holding type electromagnetic relay having the above-described configuration will be described.

For example, when no voltage is applied to the coil 22 of the electromagnet block 20 illustrated in FIG. 4, one end 31a of the movable iron piece 31 is attracted to one magnetic pole portion of the iron core 21, for example, the magnetic pole portion 21a, thereby constituting a magnetic circuit. Therefore, the movable contact 35 of the movable touch piece 33 illustrated in FIG. 3 comes into contact with the fixed contact 12, and the movable contact 36 is separated from the fixed contact 14.

When a voltage is applied to the coil 22 so as to generate a magnetic line of force in a direction canceling the magnetic lines of force of the permanent magnet 32 illustrated in FIG. 4, the other end 31b of the movable iron piece 31 illustrated in FIG. 3 is attracted to the magnetic pole portion 21b of the iron core 21 against the magnetic force of the permanent magnet 32. Hence the movable block 30 rotates about the connecting tongue piece 34 (FIG. 5). As a result, after the movable contact 36 of the movable touch piece 33 illustrated in FIG. 3 comes into contact with the fixed contact 14, the other end 31b of the movable iron piece 31 illustrated in FIG. 4 is attracted to the magnetic pole portion 21b of the iron core 21 to form a magnetic circuit.

Subsequently, even when the application of the voltage to the coil 22 is stopped, the movable block 30 keeps its state by the magnetic force of the permanent magnet 32.

Finally, a voltage in a direction opposite to the above-mentioned voltage application direction is applied to the coil 22 illustrated in FIG. 4. As a result, when the generated magnetic lines of force overcome the magnetic lines of force of the permanent magnet 32, one end 31a of the movable iron piece 31 illustrated in FIG. 4 is attracted to the magnetic pole portion 21a of the iron core 21, and the movable block 30 rotates about the connecting tongue piece 34 (FIG. 5). For this reason, after the movable contact 35 provided at one end of the movable touch piece 33 illustrated in FIG. 3 comes into contact with the fixed contact 12, one end 31a of the movable iron piece 31 illustrated in FIG. 4 is attracted to the magnetic pole portion 21a of the iron core 21.

Thereafter, the contacts are switched by repeating the same operation.

### EXAMPLE

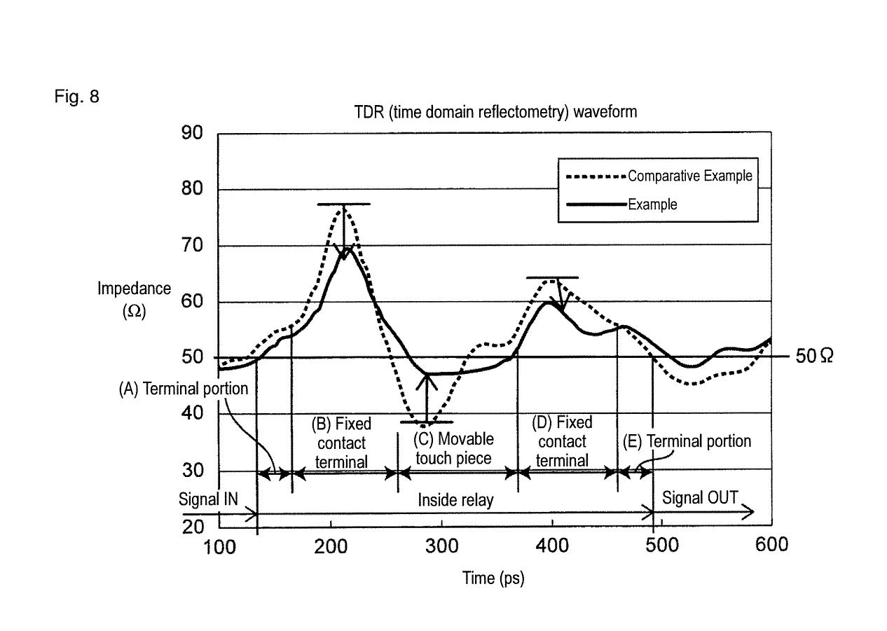

The high-frequency characteristics of the electromagnetic relay provided with the magnetic shield body 50 according to the embodiment were analyzed. The analysis result is illustrated in the graph of FIG. 8.

### COMPARATIVE EXAMPLE

As a comparative example, there was used a case where a metal case covering the entire case was covered without forming a magnetic shield body of metal plating on the case of the same electromagnetic relay as in the first embodiment. The other high-frequency characteristics were analyzed on the same conditions as in the first embodiment described above. The analysis result is illustrated in the graph of FIG. 8.

The high-frequency characteristics are measured by time domain reflectometry (TDR) method in FIG. 8. The TDR method refers to a method of applying a high-speed pulse or a step signal input to an object to be measured and measuring a returned reflection waveform. From the reflection waveform, a characteristic impedance in the course of the high-frequency transmission path can be detected. In FIG. 8,

“(A) Terminal portion” indicates a characteristic impedance of only a distal region of the common terminal 17 in FIG. 2 which is surface-mounted on a printed circuit board.

“(B) Fixed contact terminal” indicates a characteristic impedance in a region from a boundary of the distal region to the common connection receiver 16 in the common terminal 17.

“(C) Movable touch piece” indicates a characteristic impedance in a region from the base of the connecting tongue piece 34 of the movable touch piece 33 to the movable contact 36.

“(D) Fixed contact terminal” indicates a characteristic impedance in a region from the fixed contact 14 of the fixed contact terminal 15 provided on the fixed contact terminal 15 to a boundary of a distal region surface-mounted on the printed circuit board.

“(E) Terminal portion” indicates a characteristic impedance of only a distal region of the fixed contact terminal 15 which is surface-mounted on the printed circuit board.

As is apparent from FIG. 8, it was found that the reflection waveform of the example is closer to the characteristic impedance (50 0) than the reflection waveform of the comparative example. As a result, it was found that the variation in the characteristic impedance in the example is smaller, and the leakage of the high frequency signal is smaller, than in the comparative example.

### Second Embodiment

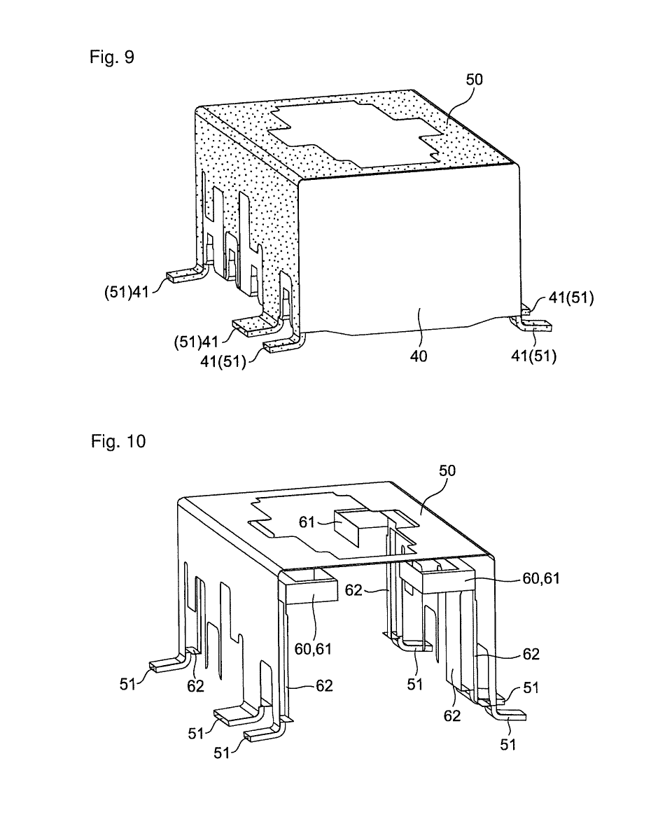

In a second embodiment, as illustrated in FIGS. 9 to 15, a magnetic shield structure according to the present invention has been applied to the case 40 of the electromagnetic relay as in the first embodiment. A difference from the first embodiment is that a magnetic shield body 60 is also formed on the inner peripheral surface of the case 40 by the MID molding method. Therefore, the difference from the first embodiment will be described, and the same parts will be denoted by the same reference numerals and the description thereof will be omitted.

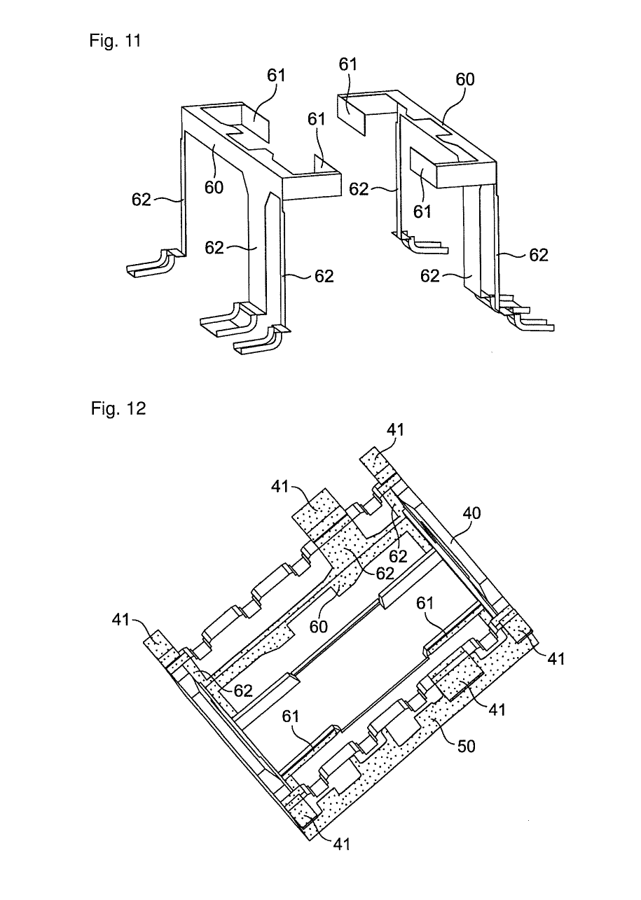

The magnetic shield body 60 is provided at each corner portion facing the inner peripheral surface of the case 40. In particular, as illustrated in FIG. 11, the magnetic shield body 60 has a pair of arms 61 extending from both ends. The arm 61 has a shape that surrounds both ends of the movable touch piece 33 of the first embodiment. Further, the magnetic shield body 60 is electrically connected to the tubular magnetic shield portion 51 of the magnetic shield body 50 via a leg 62 extending downward.

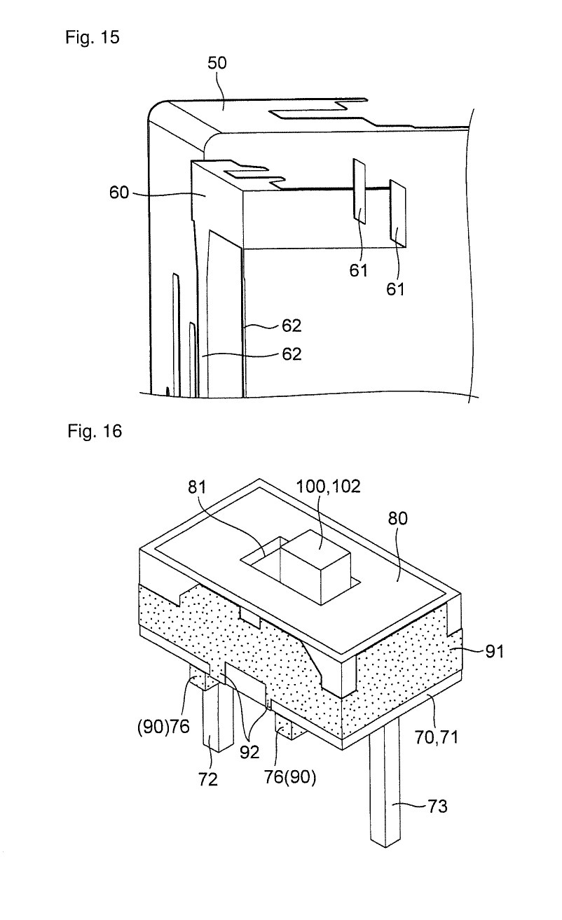

According to the embodiment, as illustrated in FIGS. 14 and 15, both ends of the movable touch piece 33 are disposed so as to form a minute gap between the magnetic shield body 60 attached to the inner surface of a case made of resin which is a dielectric and its arm 61. As a result, a coplanar line structure similar to that of the first embodiment is constituted.

Therefore, according to the second embodiment, not only the magnetic shield body 50 but also the magnetic shield body 60 is provided, whereby the characteristic impedance can be easily adjusted. For this reason, the variation in the characteristic impedance in the high-frequency transmission path is more easily reduced, and the high-frequency characteristics can be improved. There is thus an advantage that the degree of design freedom is widened to further expand the application.

### Third Embodiment

In a third embodiment, as illustrated in FIGS. 16 to 22, a magnetic shield structure according to the present invention has been applied to a switch 70. The switch 70 is formed of a plate-shaped base 71, a box-shaped case 80, and an operation lever 100 assembled to the box-shaped case 80.

As illustrated in FIG. 18, the plate-shaped base 71 is integrally molded with a pair of fixed contact terminals 72, 73 so that fixed contacts 74, 75 are exposed at both side edges of the upper surface. Further, the plate-shaped base 71 has four positioning legs 76 projecting from the lower surface thereof between the fixed contact terminals 72, 73. In the plate-shaped base 71, a magnetic shield body 90 is formed on the lower surface including the positioning legs 76 by the MID molding method.

The box-shaped case 80 has a box shape capable of covering the upper surface of the plate-shaped base 71, and an operation hole 81 is formed on the ceiling surface. In addition, the box-shaped case 80 has a magnetic shield body 91 having an annular shape and formed on its outer surface by the MID molding method. The magnetic shield body 91 is electrically connected to the magnetic shield body 90 via a connecting portion 92. Therefore, the magnetic shield body 91 can be connected to the ground via the magnetic shield body 90 covering the positioning legs 76 of the plate-shaped base 71.

As illustrated in FIG. 18, the operation lever 100 has an inverted T-shape in cross section, and a caulking projection 101 provided on the lower surface thereof is inserted and fixed into a caulking hole 108 of a movable touch piece 105. The movable touch piece 105 has a cross-sectional shape in which movable contacts 106, 107 located at both ends of the movable touch piece 105 are in contact with the fixed contacts 74, 75, respectively. The operation lever 100 protrudes from the operation hole 81 of the box-shaped case 80 so that an operation protrusion 102 protruding from the upper surface of the operation lever 100 is operable.

Therefore, by sliding the operation protrusion 102 of the operation lever 100, the movable contacts 106, 107 come into contact with the fixed contacts 74, 75, respectively. Even when a high frequency signal flows to the fixed contact terminal 72, the movable touch piece 105 and the fixed contact terminal 73, it is magnetically shielded by the magnetic shield bodies 90, 91. There is thus an advantage that not only leakage of high frequency signals but also entry of external signals can be prevented.

### Fourth Embodiment

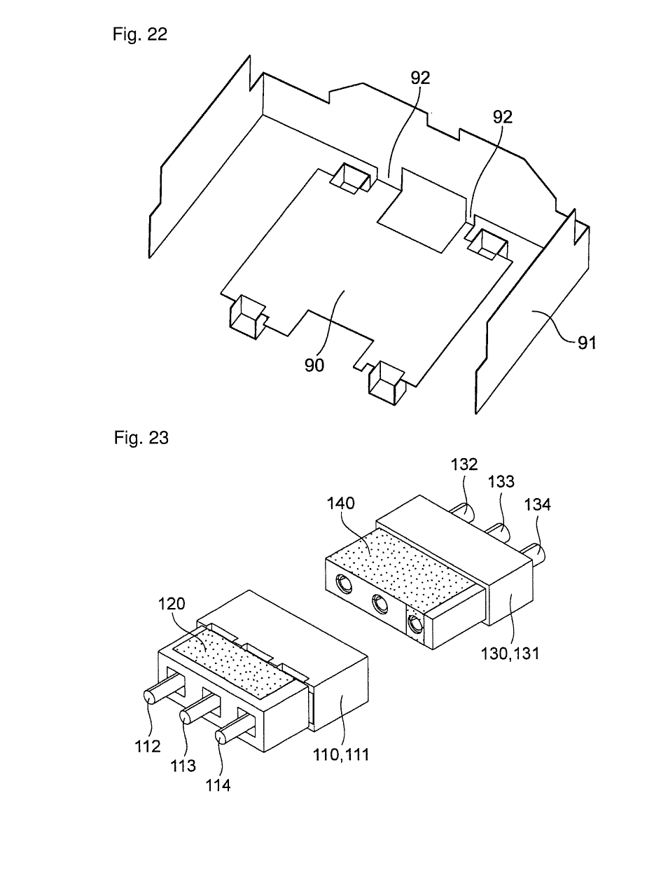

In a fourth embodiment, as illustrated in FIGS. 22 to 25, a magnetic shield structure according to the present invention has been applied to a high-frequency connector. The high-frequency connector includes a plug 110 and a socket 130.

The plug 110 is formed by integrally molding three connecting pins 112, 113, 114 disposed side by side into a plug body 111 formed of resin serving as a dielectric. A magnetic shield body 120 is formed on the plug body 111 by the MID molding method.

That is, in the magnetic shield body 120, an upper piece portion 121 and a lower piece portion 122 which are disposed so as to sandwich the connecting pins 112, 113, 114 from above and below, are electrically connected by a connecting portion 123. The connecting portion 123 is electrically connected to the connecting pin 114 connected to the ground.

Further, the socket 130 is formed by integrally molding three receiving pins 132, 133, 134 disposed side by side into a socket body 131 formed of resin serving as a dielectric. In the socket body 131, a magnetic shield body 140 is formed by the MID molding method.

That is, in the magnetic shield body 140, an upper piece portion 141 and a lower piece portion 142 which are formed so as to sandwich the receiving pins 132, 133, 134 from above and below, are electrically connected by a connecting portion 143. The connecting portion 143 is electrically connected to the receiving pin 134 connected to the ground.

A magnetic shield structure according to the present invention is not limited to the electromagnetic relay, the switch, and the connector described above, and may be applied to other electric devices and electronic components having a high-frequency transmission component in a housing made of resin.

### Description of Symbols

10 electromagnetic relay

11 base

12 fixed contact

13 fixed contact terminal

14 fixed contact

15 fixed contact terminal

16 common connection receiver

17 common terminal

18 coil terminal

20 electromagnet block

21 iron core

22 coil

23 spool

30 movable block

31 movable iron piece

32 permanent magnet

33 movable touch piece

40 case

41 terminal portion

50 magnetic shield body

51 tubular magnetic shield portion

60 magnetic shield body

61 arm

62 leg

70 switch

71 plate-shaped base

72 fixed contact terminal

73 fixed contact terminal

74 fixed contact

75 fixed contact

76 positioning leg

80 box-shaped case

81 operation hole

90 magnetic shield body

91 magnetic shield body

92 connecting portion

110 plug

111 plug body

120 magnetic shield body

121 upper piece portion

122 lower piece portion

123 connecting portion

130 socket

131 socket body

140 magnetic shield body

141 upper piece portion

142 lower piece portion

143 connecting portion

1. A magnetic shield structure, comprising:
a housing made of a dielectric material; and
a magnetic shield body formed by metal plating,
wherein the magnetic shield body is partially provided on at least one of an outer surface and an inner surface that form a surface of the housing made of the dielectric material.

2. The magnetic shield structure according to claim 1, wherein the magnetic shield body is formed by the metal plating in a region facing high-frequency transmission path disposed in the housing on the inner surface and/or the outer surface of the housing, such that a characteristic impedance of the high-frequency transmission path becomes uniform.

3. The magnetic shield structure according to claim 1, wherein the magnetic shield body is formed by the metal plating and a dielectric in a region facing the high-frequency transmission path disposed in the housing on the inner surface and/or the outer surface of the housing, such that a characteristic impedance of the high-frequency transmission path becomes uniform.

4. The magnetic shield structure according to claim 1, wherein the housing is made up of a base and a case fitted to the base.

5. The magnetic shield structure according to claim 4, wherein the magnetic shield body is formed on at least a part of an outer surface of the case.

6. The magnetic shield structure according to claim 4, wherein the magnetic shield body is formed on at least a part of an inner surface of the case.

7. The magnetic shield structure according to claim 4, wherein the magnetic shield body formed on the outer surface of the case and the magnetic shield body formed on the inner surface of the case are electrically connected by the metal plating.

8. The magnetic shield structure according to claim 4, wherein the magnetic shield body is formed on at least a part of a bottom surface of the base.

9. The magnetic shield structure according to claim 4, wherein the magnetic shield body formed on the outer surface of the case and the magnetic shield body formed on the bottom surface of the base are electrically connected by the metal plating.

10. The magnetic shield structure according to claim 1, wherein the housing is made up of a plug body and a socket body connected to the plug body.

11. The magnetic shield structure according to claim 10, wherein the magnetic shield body is formed by the metal plating on at least a part of the plug body.

12. The magnetic shield structure according to claim 10, wherein the magnetic shield body is formed by the metal plating on at least a part of the socket body.

13. An electric/electronic component comprising:
a magnetic shield structure, comprising:
a housing made of a dielectric material; and
a magnetic shield body formed by metal plating,
wherein the magnetic shield body is partially provided on at least one of an outer surface and an inner surface that form a surface of the housing.

14. The magnetic shield structure according to claim 2, wherein the magnetic shield body is formed by the metal plating and a dielectric in a region facing the high-frequency transmission path disposed in the housing on the inner surface and/or the outer surface of the housing, such that a characteristic impedance of the high-frequency transmission path becomes uniform.

15. The magnetic shield structure according to claim 2, wherein the housing is made up of a base and a case fitted to the base.

16. The magnetic shield structure according to claim 3, wherein the housing is made up of a base and a case fitted to the base.

17. The magnetic shield structure according to claim 5, wherein the magnetic shield body is formed on at least a part of an inner surface of the case.

18. The magnetic shield structure according to claim 5, wherein the magnetic shield body formed on the outer surface of the case and the magnetic shield body formed on the inner surface of the case are electrically connected by the metal plating.

19. The magnetic shield structure according to claim 6, wherein the magnetic shield body formed on the outer surface of the case and the magnetic shield body formed on the inner surface of the case are electrically connected by the metal plating.

20. The magnetic shield structure according to claim 5, wherein the magnetic shield body is formed on at least a part of a bottom surface of the base.
